(19) United States
(12) Patent Application Publication
(10) Pub. No.: US 2013/0229202 A1
(43) Pub. Date: Sep. 5, 2013

(54) POWER TEST APPARATUS FOR POWER SUPPLY

(71) Applicants: Xiao-Gang Yin, Shenzhen (CN); Guo-Yi Chen, Shenzhen (CN)

(72) Inventors: Xiao-Gang Yin, Shenzhen (CN); Guo-Yi Chen, Shenzhen (CN)

(21) Appl. No.: 13/682,605

(22) Filed: Nov. 20, 2012

(30) Foreign Application Priority Data
Mar. 5, 2012 (CN) 201210054497.6

(51) Int. Cl. G01R 1/04

(52) U.S. Cl. CPC G01R 1/0408; G01R 1/0416
USPC 324/756.05; 324/756.07

(57) ABSTRACT

A power test board for a power supply includes a main board and a load circuit. The load circuit includes at least one switch, at least one control circuit, and at least one load resistor. A number of the load resistor being same with a number of the control circuit, each load resistor is electronically connected to one of the at least one control circuit. Toggling of the at least one switch to electronically connect to the control circuit causes the control circuit to be electronically connected to the power supply, the at least one control circuit is turned on, and the at least one load resistor is activated to serve as a load of the power supply.

### BACKGROUND

1. Technical Field

The disclosure generally relates to power test apparatuses, and particularly to a power test apparatus for a power supply.

2. Description of the Related Art

Many electronic devices, such as servers, employ a motherboard and a power supply providing power for the motherboard. In order to test power range of the power supply, the power supply must be electronically connected to different loads (e.g., a motherboard). Thus, operators can immediately know the power range of the power supply. However, it may be inconvenient for the operators to have to connect/disconnect the power supply to/from the different loads.

Therefore, there is room for improvement within the art.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present embodiments.

FIG. 1 is a block diagram of a power test device for a power supply, according to an exemplary embodiment.

FIG. 2 is a circuit view of the power test device as shown in FIG. 1.

### DETAILED DESCRIPTION

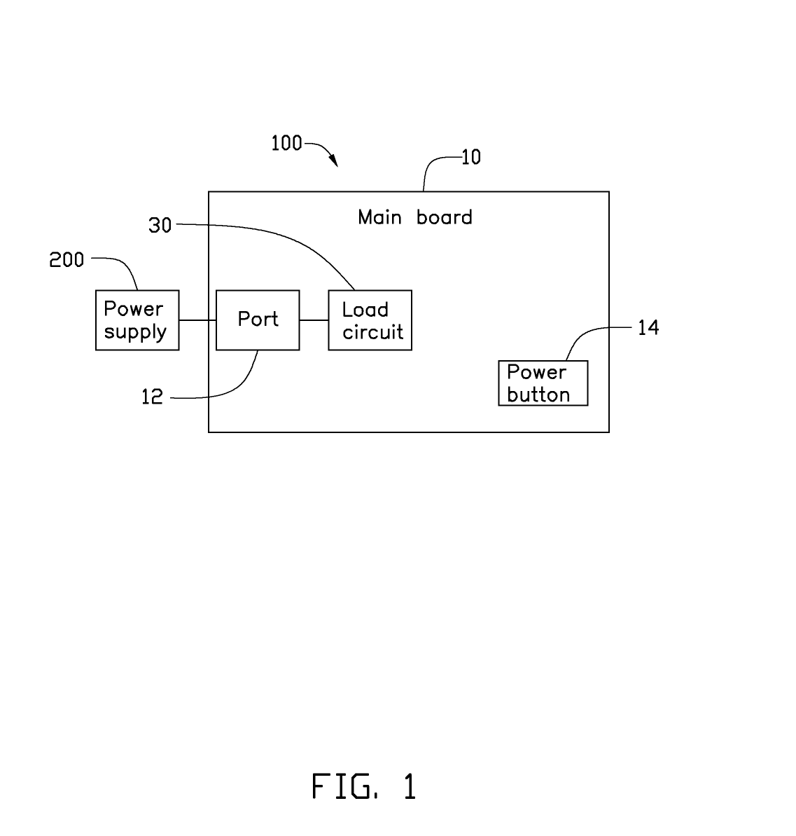

FIG. 1 shows an exemplary embodiment of a power test device 100. The power test device 100 is configured to test a power range of a power supply 200.

The power test device 100 includes a main board 10 and a load circuit 30 integrated on the main board 10. The main board 10 can be a motherboard of an electronic device (not shown), such as a server.

The main board 10 includes a port 12 and a power button 14. The main board 10 is electronically connected to the power supply 200 via the port 12. When the power button 14 is actuated, the main board 10 is activated. The main board 10 receives power from the power supply 200, and provides a standby voltage source 5VSB, a first driving voltage source 5V, and a second driving voltage source 12V to the load circuit 30. Specifically, the standby voltage source 5VSB is generated as long as the main board 10 is electronically connected to the power supply 200, the first driving voltage source 5V and the second driving voltage source 12V are generated when the button 14 is actuated.

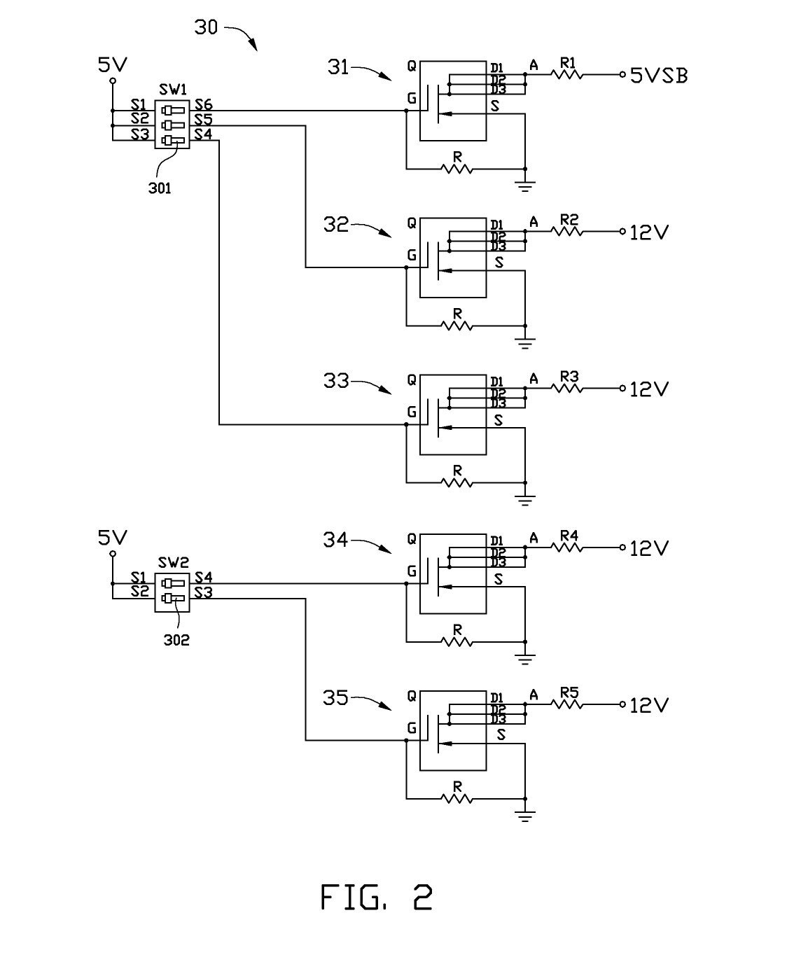

FIG. 2 shows that in one exemplary embodiment, the load circuit 30 includes a first switch SW1, a second switch SW2, five control circuits 31, 32, 33, 34, and 35, and five load resistors R1, R2, R3, R4, and R5. A total power consumption of the load circuit 30 can be changed through activating a different number of the five load resistors R1, R2, R3, R4, and R5.

In one exemplary embodiment, the first switch SW1 activates the control circuits 31, 32, and 33. The first switch SW1 is a toggle switch, and includes a first terminal S1, a second terminal S2, a third terminal S3, a fourth terminal S4, a fifth terminal S5, and a sixth terminal S6. The first switch SW1 further includes three switch toggles 301 (or levers, buttons, etc). The first terminal S1 can be electronically connected to/disconnected from the sixth terminal S6 by manipulation of one of the three switch toggles 301. The second terminal S2 can be electronically connected to/disconnected from the fifth terminal S5 by manipulation of one of the three switch toggles 301. The third terminal S3 can be electronically connected to/disconnected from the fourth terminal S4 by manipulation of one of the three switch toggles 301. The first terminal S1, the second terminal S2, and the third terminal S3 are all electronically connected to the first driving voltage source 5V, the fourth terminal S4, the fifth terminal S5, and the sixth terminal S6 are electronically connected to the control circuits 31, 32, and 33, respectively.

In one exemplary embodiment, the second switch SW2 activates the control circuits 34 and 35. The second switch SW2 is a toggle switch, and includes a first terminal S1, a second terminal S2, a third terminal S3, and a fourth terminal S4. The first switch SW1 further includes two switch toggles 302 such as levers or buttons, for example. The first terminal S1 can be electronically connected to/disconnected from the fourth terminal S4 by manipulation of one of the two switch toggles 302. The second terminal S2 can be electronically connected to/disconnected from the third terminal S3 by manipulation of one of the two switch toggles 302. Both the first terminal S1 and the second terminal S2 are electronically connected to the first driving voltage source 5V, the third terminal S3 and the fourth terminal S4 are electronically connected to the control circuits 34, and 35, respectively.

Each of the five control circuits 31, 32, 33, 34, and 35 includes a metallic oxide semiconductor field effect transistor (MOSFET) Q and a bias resistor R. The MOSFET Q is in a form of an 8-pin microchip, and is used to stabilize output voltages. The MOSFET Q includes a gate G, a source S, and drains D1, D2, and D3. The gate G is electronically connected to ground via the bias resistor R, the source S is electronically connected to ground, and the drains D1, D2, and D3 are electronically interconnected to form a node A.

Additionally, the gate G of the MOSFET Q of the control circuit 31 is electronically connected the sixth terminal S6 of the first switch SW1. The gate G of the MOSFET Q of the control circuit 32 is electronically connected the fifth terminal S5 of the first switch SW1. The gate G of the MOSFET Q of the control circuit 33 is electronically connected the fourth terminal S4 of the first switch SW1. The gate G of the MOSFET Q of the control circuit 34 is electronically connected the fourth terminal S4 of the second switch SW2. The gate G of the MOSFET Q of the control circuit 35 is electronically connected the third terminal S3 of the second switch SW2.

The load resistor R1 is electronically connected between the standby voltage source 5VSB and the node A of the control circuit 31. The load resistor R2 is electronically connected between the second driving voltage source 12V and the node A of the control circuit 32. The load resistor R3 is electronically connected between the second driving voltage source 12V and the node A of the control circuit 33. The load resistor R4 is electronically connected between the second driving voltage source 12V and the node A of the control circuit 34. The load resistor R5 is electronically connected between the second driving voltage source 12V and the node A of the control circuit 35. In one exemplary embodiment, rated power consumptions of the load resistors R1, R2, R3, R4, and R5 are all about 50 watts.

When the power range of the power supply 200 is tested, the power supply 200 is electronically connected to the main board 10 via the port 12. Thus, the main board 10 supplies the standby voltage source 5VSB to the load circuit 30. When the power button 14 is actuated, the main board 10 supplies the first driving voltage source 5V and the second driving voltage source 12V to the load circuit 30.

If a rated power of the power supply 200 is about 160 watts, then operators manipulate the switch toggles 301 of the first switch SW1 to allow the first terminal S1 to be electronically connected to the sixth terminal S6, the second terminal S2 to be electronically connected to the fifth terminal S5, the third terminal S3 to be electronically connected to the fourth terminal S4. Thus, the gates G of the control circuits 31, 32, and 33 receive a high voltage (e.g., 5V) from the first driving voltage source 5V. Then, the MOSFET Q of the control circuits 31, 32, and 33 are turned on, and the load resistors R1, R2, and R3 are activated. The total power consumption of the load resistors R1, R2, and R3 is about 150 watts. In the above example, if the power supply works normally, the maximum power of the power supply 200 may reach 150 watts, and is approaching to the rated power of the power supply 200. If the power supply works abnormally (e.g., turn off), the maximum power of the power supply 200 may not reach 150 watts.

If a rated power of the power supply 200 is about 120 watts, then operators manipulate the switch toggles 302 of the second switch SW2 to allow the first terminal S2 to be electronically connected to the fourth terminal S4, the second terminal S2 to be electronically connected to the third terminal S3. Thus, the gates G of the control circuits 34, and 35 receive a high voltage (e.g., 5V) from the first driving voltage source 5V. Then, the MOSFETs Q of the control circuits 31, and 35 are turned on, and the load resistors R4, and R5 are activated. The total power consumption of the load resistors R4, and R5 is about 100 watts. In the above example, if the power supply works normally, the maximum power of the power supply 200 may reach 100 watts, and is approaching to the rated power of the power supply 200. If the power supply works abnormally (e.g., turn off), the maximum power of the power supply 200 may not reach 100 watts.

In other embodiments, one of the first switch SW1 and the second switch SW2 can be omitted. For example, if the second switch SW2 is omitted, the power test device 100 can test the rated power of the power supply 200 of about 50-150 watts through the first switch SW1, the control circuits 31, 32, and 33, and load resistors R1, R2, and R3.

In other embodiments, the rated power consumptions of the load resistors R1, R2, R3, R4, and R5 can be different, for example, the rated power consumptions of the load resistors R1, R2, and R3 are all about 45 watts, and the rated power consumptions of the load resistors R4, and R5 are both about 30 watts.

In summary, the operators can manipulate the first switch SW1 and the second SW2 to turn on the at least one of the control circuits 31, 32, 33, 34, and 35, and then the corresponding load resistors R1, R2, R3, R4, and R5 are activated and are served as the load of the power supply 200. Thus, the power test device 100 can test the power range of the power supply 200. Additionally, the power supply 200 does not need to physically and repeatedly be connected to/disconnected from different loads. Therefore, the power test device 100 is both efficient and convenient.

Although numerous characteristics and advantages of the exemplary embodiments have been set forth in the foregoing description, together with details of the structures and functions of the exemplary embodiments, the disclosure is illustrative only, and changes may be made in detail, especially in the matters of arrangement of parts within the principles of disclosure to the full extent indicated by the broad general meaning of the terms in which the appended claims are expressed.

What is claimed is:

1. A power test board for a power supply, the power test board comprising:
a main board electronically connected to the power supply; and
a load circuit integrated on the main board, and comprising at least one switch, at least one control circuit, and at least one load resistor, a number of the load resistor being same with a number of the control circuit, each load resistor electronically connected to one of the at least one control circuit;
wherein toggling of the at least one switch to electronically connect to the control circuit causes the control circuit to be electronically connected to the power supply, the at least one control circuit is turned on when the at least one control circuit receives power from the power supply, and the at least one load resistor is activated to serve as a load of the power supply.

2. The power test board as claimed in claim 1, wherein the main board includes a port, the main board is electronically connected to the power supply via the port.

3. The power test board as claimed in claim 1, wherein the main board includes a power button, when the power button is actuated, the main board is activated.

4. The power test board as claimed in claim 1, wherein the main board receives power from the power supply, and provides a standby voltage source, a first driving voltage source, and a second driving voltage source to the load circuit.

5. The power test board as claimed in claim 4, wherein the at least one switch is electronically connected to the first driving voltage source, the at least one load resistor is electronically connected to the standby voltage source or the second driving voltage source.

6. The power test board as claimed in claim 5, wherein each control circuit includes a metallic oxide semiconductor field effect transistor (MOSFET) and a bias resistor, the MOSFET includes a gate, a source, and three drains, the gate is electronically connected to ground via the bias resistor, the source is electronically connected to ground, and the three drains are electronically interconnected to form a node.

7. The power test board as claimed in claim 6, wherein the at least one load resistor is electronically connected between the node and the standby voltage source or the second driving voltage source.

8. The power test board as claimed in claim 7, wherein the at least one switch includes a first switch, the first switch is a toggle switch, and includes a first terminal, a second terminal, a third terminal, a fourth terminal, a fifth terminal, a sixth terminal, and three switch toggles, the first terminal is electronically connected to/disconnected from the sixth terminal by manipulation of one of the three switch toggles, the second terminal is electronically connected to/disconnected from the fifth terminal by manipulation of one of the three switch toggles, the third terminal is electronically connected to/disconnected from the fourth terminal by manipulation of one of the three switch toggles.

9. The power test board as claimed in claim 8, wherein the first terminal, the second terminal, and the third terminal are electronically connected to the first driving voltage source, the fourth terminal is electronically connected to the gate of one of the MOSFET, the fifth terminal is electronically connected to the gate of one of the MOSFET, and the sixth terminal is electronically connected to the gate of one of the MOSFET.

10. The power test board as claimed in claim 7, wherein the at least one switch includes a second switch, the second switch is a toggle switch, and includes a first terminal, a second terminal, a third terminal, a fourth terminal, and two switch toggles, the first terminal is electronically connected to/disconnected from the fourth terminal by manipulation of one of the two switch toggles, the second terminal is electronically connected to/disconnected from the third terminal by manipulation of one of the two switch toggles.

11. The power test board as claimed in claim 10, wherein the first terminal and the second terminal are electronically connected to the first driving voltage source, the third terminal is electronically connected to the gate of one of the MOSFET, and the fourth terminal is electronically connected to the gate of one of the MOSFET.

12. A power test board for a power supply, the power test board comprising:
a main board electronically connected to the power supply; and
a load circuit integrated on the main board, and comprising a first switch, a second switch, at least one control circuit, and at least one load resistor, a number of the load resistor being same with a number of the control circuit, each load resistor electronically connected to one of the at least one control circuit;
wherein toggling of the first switch to electronically connect to the at least one control circuit causes the at least one control circuit to be electronically connected to the power supply, the at least one control circuit is turned on when the at least one control circuit receives power from the power supply, and the at least one load resistor is activated to serve as a load of the power supply; and
wherein toggling of the second switch to electronically connect to the at least one control circuit causes the at least one control circuit to be electronically connected to the power supply, the at least one control circuit is turned on when the at least one control circuit receives power from the power supply, and the at least one load resistor is activated to serve as a load of the power supply.

13. The power test board as claimed in claim 12, wherein the main board receives power from the power supply, and provides a standby voltage source, a first driving voltage source, and a second driving voltage source to the load circuit.

14. The power test board as claimed in claim 13, wherein the at least one switch is electronically connected to the first driving voltage source, the at least one load resistor is electronically connected to the standby voltage source or the second driving voltage source.

15. The power test board as claimed in claim 14, wherein each control circuit includes a metallic oxide semiconductor field effect transistor (MOSFET) and a bias resistor, the MOSFET includes a gate, a source, and three drains, the gate is electronically connected to ground via the bias resistor, the source is electronically connected to ground, and the three drains are electronically interconnected to form a node.

16. The power test board as claimed in claim 15, wherein the at least one load resistor is electronically connected between the node and the standby voltage source or the second driving voltage source.

17. The power test board as claimed in claim 16, wherein the first switch is a toggle switch, and includes a first terminal, a second terminal, a third terminal, a fourth terminal, a fifth terminal, a sixth terminal, and three switch toggles, the first terminal is electronically connected to/disconnected from the sixth terminal by manipulation of one of the three switch toggles, the second terminal is electronically connected to/disconnected from the fifth terminal by manipulation of one of the three switch toggles, the third terminal is electronically connected to/disconnected from the fourth terminal by manipulation of one of the three switch toggles.

18. The power test board as claimed in claim 17, wherein the first terminal, the second terminal, and the third terminal are electronically connected to the first driving voltage source, the fourth terminal is electronically connected to the gate of one of the MOSFET, the fifth terminal is electronically connected to the gate of one of the MOSFET, and the sixth terminal is electronically connected to the gate of one of the MOSFET.

19. The power test board as claimed in claim 16, wherein the second switch is a toggle switch, and includes a first terminal, a second terminal, a third terminal, a fourth terminal, and two switch toggles, the first terminal is electronically connected to/disconnected from the fourth terminal by manipulation of one of the two switch toggles, the second terminal is electronically connected to/disconnected from the third terminal by manipulation of one of the two switch toggles.

20. The power test board as claimed in claim 19, wherein the first terminal and the second terminal are electronically connected to the first driving voltage source, the third terminal is electronically connected to the gate of one of the MOSFET, and the fourth terminal is electronically connected to the gate of one of the MOSFET.
